(19) United States
(12) Patent Application Publication
(10) Pub. No.: US 2023/0130622 A1
(43) Pub. Date: Apr. 27, 2023

(54) NON-INTRUSIVE ELECTRICAL CURRENT DETECTION SYSTEM AND METHOD

(71) Applicant: S.J. Electro Systems, LLC, Detroit Lakes, MN (US)

(72) Inventor: Corey Lee Steinke, Detroit Lakes, MN (US)

(73) Assignee: S.J. Electro Systems, LLC, Detroit Lakes, MN (US)

(21) Appl. No.: 17/970,418

(22) Filed: Oct. 20, 2022

Related U.S. Application Data
(60) Provisional application No. 63/270,774, filed on Oct. 22, 2021.

(51) Int. Cl. G01R 19/00; G01R 33/00; G01R 33/02; G01R 33/07

(52) U.S. Cl. CPC G01R 19/0092; G01R 33/0047; G01R 33/0206; G01R 33/072

(57) ABSTRACT

A non-intrusive electrical current detector system and method is disclosed. In one example, the system includes a magnetic field sensing device and a controller. The system provides a user with a way to monitor the running status of an electrical device, without the need to make electrical connections or separating conductors in a multi-conductor cable.

### CROSS-REFERENCE TO RELATED APPLICATION

The present application is a non-provisional application of U.S. Provisional Patent Application Ser. No. 63/270,774, filed Oct. 22, 2021, which is incorporated herein by reference.

### BACKGROUND

There are several common methods for detecting current in electrical circuits without the need to directly connect to electrical conductors. For these common methods of non-intrusive current detecting devices, typically, a single conductor of the electrical circuit must be isolated and routed through the current detection device.

For a magnetically coupled current detecting device, the installation requires separating the supply conductors so that a single conductor can be routed through a magnetic core, which typically needs to be done either at the source of the electrical power or close to the electrical load. This poses a problem for electrical devices that utilize an integral power cord and are connected directly to a power receptacle.

To be able to detect electrical current in a multi-conductor cable that employs both the supply current, as well as the return current, the present methods of current detection are ineffective, as the magnetic fields effectively cancel each other. For this reason and for other reasons stated below, which will become apparent to those skilled in the art upon reading and understanding the present specification, there is a need in the art for an improved and effective system for detecting the electrical current of a device utilizing a multi-conductor cable.

For these and other reasons, a need exists for the present invention.

### SUMMARY

The above mentioned shortcoming of electrical current sensing methods are addressed by embodiments of the present invention and will be understood by reading and studying the following specification. The following summary is made by way of example and not by way of limitation. It is merely provided to aid the reader in understanding some of the aspects of the invention.

One or more embodiments of the present invention provide a user with a way to detect the electrical current of a device, without the need to make electrical connections or to separate the power conductors in a multi-conductor cable. Therefore, the user can install the electrical current detection device anywhere along the electrical power cable without disturbing the outer insulating jacket.

One or more embodiments and other examples are described in broad terms in the below paragraphs. Further aspects will become apparent from consideration of the drawings and the description of embodiments of the invention. The present disclosure is an exemplification of the principles of the invention and is not intended to limit the invention to the particular embodiments illustrated or described. A person skilled in the art will realize that other embodiments of the invention are possible and that the details of the invention can be modified in a number of respects, all without departing from the inventive concept. This, the drawings, and description are to be regarded as illustrative in nature and not restrictive.

### BRIEF DESCRIPTION OF THE DRAWINGS

FIGS. 1-10 illustrate one or more examples of a non-intrusive electrical current detector, a system including a non-intrusive electrical current detector, and a method of using a non-intrusive electrical current detector.

FIG. 1 is a block diagram illustrating one example of a non-intrusive electrical current detection system.

FIG. 2 is a diagram illustrating one example of a non-intrusive electrical current detector system used as part of an electrical device monitoring system.

FIG. 3 is a block diagram illustrating another example of a non-intrusive current detection system.

FIG. 4 is a diagram illustrating one example of a non-intrusive current detector.

FIG. 5 is a diagram illustrating one example of a top view of the non-intrusive current detector of FIG. 4.

FIG. 6 is a diagram illustrating one example of a side view of the non-intrusive current detector of FIG. 4.

FIG. 7 is a diagram illustrating one example of a mechanism for securing a non-intrusive current detector to a multi-conductor cable.

FIG. 8 is a magnetic field diagram illustrating one example of a non-intrusive current detector positioned near a multiple conductor cable.

FIG. 9 is a magnetic field diagram illustrating one example of a non-intrusive current detector positioned near a multiple conductor cable.

FIG. 10 is a diagram illustrating one example of a method of monitoring an electrical device.

### DETAILED DESCRIPTION

In the following Detailed Description, reference is made to the accompanying drawings which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized, and structural or logical changes may be made without departing from the scope of the present invention. The following detailed description, therefore, is not to be taken in a limiting sense, and the scope of the present invention is defined by the appended claims.

A non-intrusive electrical current detector system, device and method is disclosed. In one or more examples, the system and device provide a user with a way to detect the presence of electrical current in a cable feeding an electrical device, without the need to make electrical connections. In one example, a user can install the non-intrusive electrical current detector anywhere along an electrical power cable that feeds the electrical device. This is a very useful aid in tracking run time of an electrical device. In one application, this type of detector system is used to track run time in a water or wastewater pump system.

Due to the cancellation of electrical current induced magnetic fields because of the opposite direction of the feed current and return current paths, a unique way of sensing the opposing magnetic fields is needed. In order to reliably sense these magnetic fields produced by an electrical current in a multi-conductor cable, the present unique design uses a plurality of magnetic field sensing elements or multiple axes on a single sensing element. Due to the small physical offsets of electrical conductors contained within a cable relative to the position of the multiple magnetic field sensing device, at least one or both of the sensing elements will be closer to one of the current carrying conductors resulting in the presence of a magnetic field. The plurality of magnetic field sensing devices are able to sense the uncanceled magnetic field.

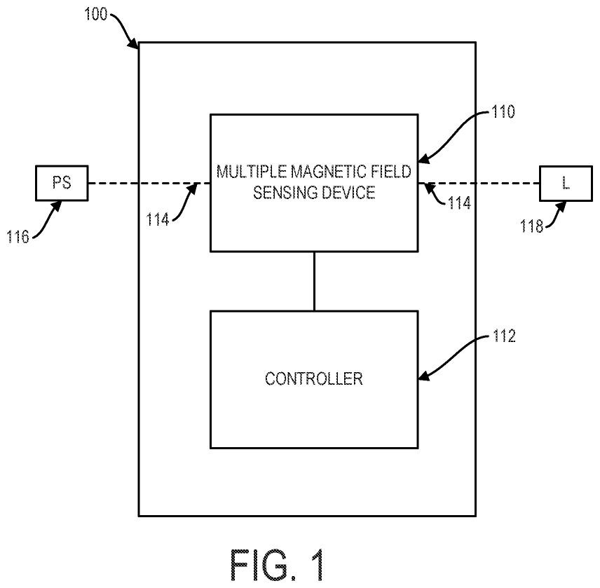

FIG. 1 illustrates one example of a non-intrusive electrical current detector system at 100. The system 100 includes a multiple (e.g., 2-axis or two, single axis) magnetic field sensing device 110 in communication with a controller 112. The multiple magnetic field sensing device 110 is configured to be installed at any location along a multi-conductor cable 114 between a power source 116 and an electric device (load) 118. In operation, the multiple magnetic field sensor 110 serves to sense a nearby electrical current by sensing the magnetic field created by the current on one or more sensing axes. A magnetic field is sensed when current is present in the multi-conductor cable. As such, the multiple magnetic field sensing device 110 provides an output indicating the presence (or absence) of an electrical current in the multi-conductor cable.

The multiple magnetic field sensing device 110 is in a common housing with the controller 112. In other examples, the multiple magnetic field sensing device 110 is in its own housing, separately located from the controller 112.

The multiple magnetic field sensing device is a multiple axis magnetic field sensing device. In one embodiment, the multiple magnetic field sensor comprises multiple single axis magnetic field sensing devices (e.g., 2 or 3 devices). In other embodiments, the multiple magnetic field sensing device is a 2-axis or 3-axis magnetic field sensing device. In other embodiments, the multiple magnetic field sensing device is made of one or more multiple axis magnetic field sensing devices.

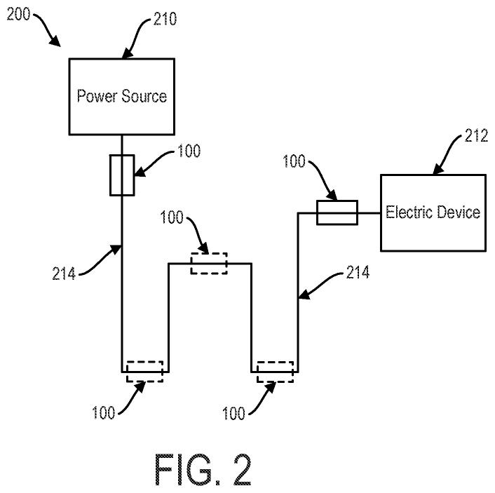

FIG. 2 illustrates one example of a non-intrusive electrical current detector system 100 used as part of an electrical device monitoring system 200. The electrical device monitoring system 200 can be part of a number of electrical device applications, such as a water pump monitoring system or a wastewater pump monitoring system. Power source 210 feeds electrical device 212 (i.e., an electrical load such as a pump) via multi-conductor cable 214. Non-intrusive current detector 100 can be positioned at any location along multi-conductor cable 100 (as shown) to measure the presence of current. The location of non-intrusive current detector 100 is not limited to being near the power source 210 or the electric device 212. The location of detector 100 is very flexible, as illustrated in FIG. 2.

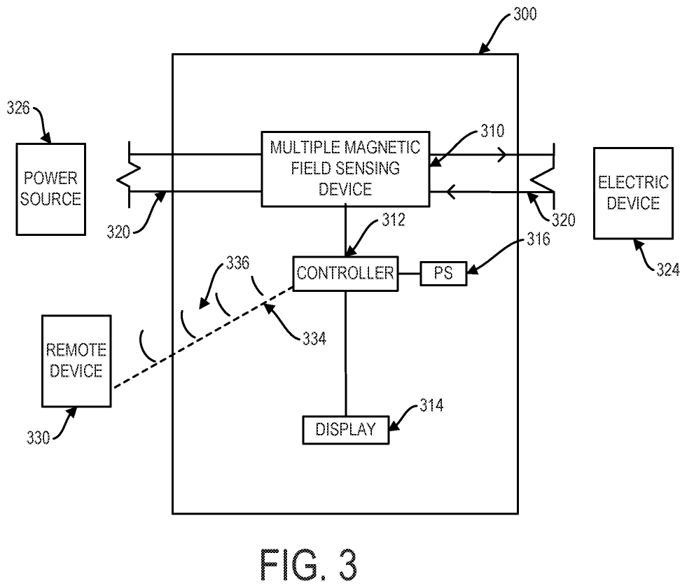

FIG. 3 illustrates another example of a non-intrusive electrical current detector system at 300. The system 300 includes a multiple magnetic field sensing device 310, which is similar to the multiple magnetic field sensing device 110 described herein. The multiple magnetic field sensing device 310 is a multiple axis magnetic field sensing device. In one embodiment, the multiple magnetic field sensor comprises multiple single axis magnetic field sensing devices (e.g., 2 or 3). In other embodiments, the multiple magnetic field sensing device is a 2-axis or 3-axis magnetic field sensing device. In other embodiments, the multiple magnetic field sensing device is made of one or more multiple axis magnetic field sensing devices.

The system further includes a controller 312 (e.g., a micro controller or control system), a numeric or visual display 314 and a power source 316. The multiple axis magnetic field sensing device 310 is positioned near or about power conductors of a multi-conductor power cable 320 feeding an electric device or load 324. In one example, electrical device 324 is powered from power source 326 using multi-conductor cable 320, and multiple magnetic field sensing device 310 is made up of two single axis magnetic field sensing devices. The multiple magnetic field sensing device 310 serves to sense a nearby electrical current by sensing the magnetic field created by the current on either or both of the multiple sensing axes. Controller 312, powered by local power source 316, then takes the signal generated by the magnetic field sensor 310 and decides if a threshold for the presence of an electrical current has been met on either or both of the sensing axes. In one example, the status or history of the status of the device being monitored is then output to the numeric or visual display 314 for a user to observe. In one example, the run time of electrical load 324 is logged using sensor 310 and visual display 314.

In one example, the non-intrusive electrical current detector system 300 provides an output signal to a remotely located device 330. The output signal is representative of the on-time or run time of electrical device 324, and corresponds to the output of multiple magnetic field sensing device 310. In one case, the output signal 332 is transmitted to remote device 330 using a wired communication link indicated as output signal 334. In another case, the output signal is transmitted to remote device 330 via a wireless communication link indicated as output signal 336. For example, the wireless communication link could be a WIFi or Bluetooth connection. The output signal 332 can be communicated to a remote device 330 from controller 312.

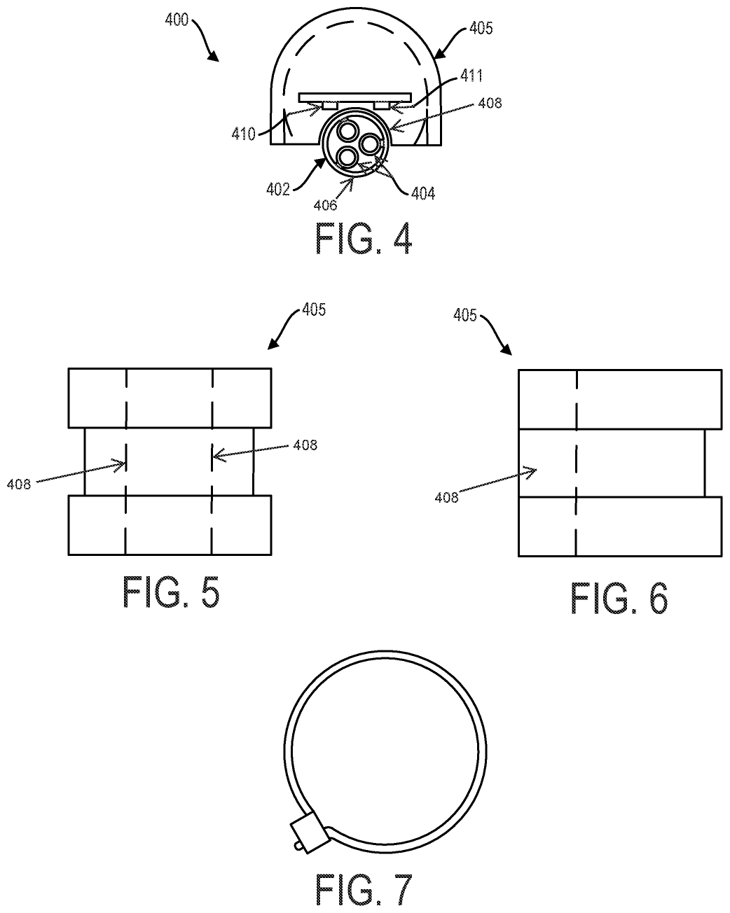

FIGS. 4-7 illustrate one example of a non-intrusive electrical current detector system generally at 400. As illustrated, the non-intrusive electrical current detector system 400 is very small and compact in size. FIG. 4 is an end view of the non-intrusive electrical current detector system 400. System 400 is one example of system 100 and system 300 previously discussed herein. System 400 is illustrated positioned about a multi-conductor cable 402, shown in cross-sectional view. In the example illustrated, the multi-conductor cable includes three conductors 404 (e.g., a power, neutral and ground conductor) and are shown positioned within cable jacket 406.

The system 400 includes a housing 405. In one example, two single axis magnetic field sensors 410, 411 are positioned on a printed circuit board (PCB) within the housing 405. Housing 405 may also include other devices, such as a power source (e.g., a battery) a display (e.g. to indicate the presence of current in the conductors), and a controller.

The housing 405 includes a longitudinally extending notch 408 that aids in positioning and retaining the housing 405 over the multi-conductor cable 402, such that the magnetic field sensors 410, 411 are near or in close proximity to the cable 402. FIG. 5 is a top view of housing 405 showing notch 408 extending through the housing 405. FIG. 6 is a side view of housing 405 further illustrating notch 408. FIG. 7 illustrates a mechanism 409 used retain the cable 402 within the notch 408 of system 400. In the example illustrated, the mechanism 209 is cable tie. In other examples, the mechanism 209 could be made up of other retaining devices. Additionally, the cable 402 could simply be retained against the detector system 400 housing 405 and not positioned within a notch.

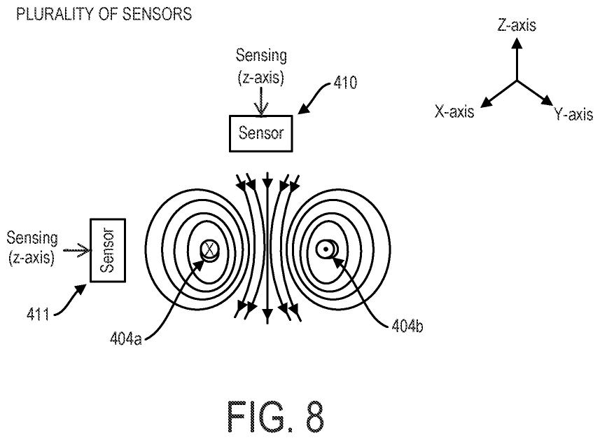

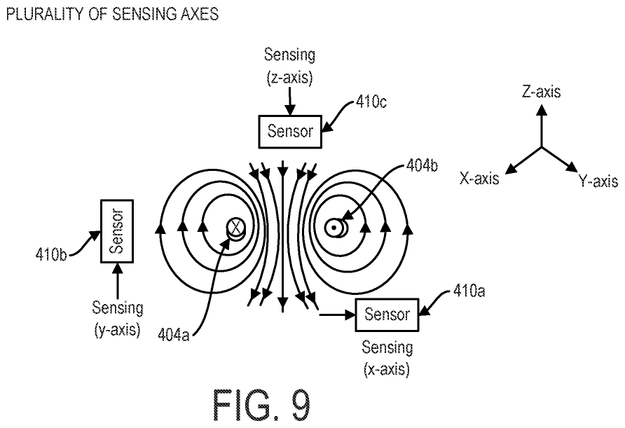

As illustrated in FIG. 4, conductors 404 vary in distance from sensors 410, 411. The corresponding sensed magnetic field associated with current flow through conductors 404 does not cancel out due to the varied distance and position or orientation of each sensor 410,411. This is further illustrated in the magnetic field diagrams of FIG. 8 and FIG. 9 for cable 402.

FIG. 8 illustrates one example of two single axis magnetic field sensors 410, 411 positioned relative to the magnetic fields of conductors 404 (illustrated as conductors 404a, 404b). As positioned, sensor 410 senses or detects the magnetic field in the z-axis. Sensor 411, positioned in a different location relative to conductors 404a,b, detects no magnetic field in the z-axis. Accordingly, when current is present in the cable 402 conductors 404a,404b the sensors 410 and 411 will indicate the presence of a magnetic field. If a traditional donut current sensor was positioned around cable 402, the resulting sensed magnetic fields would be zero. This traditional method would require that a cable jacket be opened up to gain access to individual conductors. This is not necessary for the present design.

FIG. 9 illustrates one example of one or more devices having a plurality of sensing axis, indicated as sensors 410a, 410b, and 410c. Based on the location of the sensors relative to each conductor 404, these sensors 410a, 410b, 410c sense the presence, absence or strength of magnetic field in their respective sensing axis x, y or z. As such, a magnetic field reading would exist when there is current present in the conductors 404a and 404b.

In one embodiment, the magnetic field sensing device or magnetic field sensor includes a multiple axis Hall effect sensor. In another example, a multiple axis magneto-resistive device may be used to sense the magnetic field of the electrical current in the cable 402. In other examples, multiple, individual magnetic field sensing devices may be used to sense the presence of electrical current. Other types of magnetometers may also be used to sense the magnetic field of the electrical current.

The display may be an integrally mounted LED display. Alternatively, the non-intrusive electrical current detector may use a remotely located display. Also, a separate device may be used for displaying the monitored and historic data.

The power source provides electrical power to the non-intrusive electrical current detector system. In one or more embodiments, the power source is a battery, solar cell, or energy harvesting device.

A controller is capable of storing and displaying the count of power cycles of the device being monitored. In one embodiment, the controller can send monitored and historic data via a wired connection or wirelessly to a remote location to be displayed and/or manipulated as illustrated in FIG. 3. Stored data can be manipulated based on the type of device being monitored and customized based on the device type.

In one example, the monitored device is an electrical motor driven water pump or wastewater pump, where the non-intrusive electrical current detector displays the totalized volume of water pumped, based on the flow rate of the pump and the amount of time the pump has been running (pump run time).

Stored data can also be manipulated to show the totalized power used by an electrical device based upon the history of the time the device was energized and the power required by the device. The stored data can be used to indicate a critical lifecycle of a device being monitored.

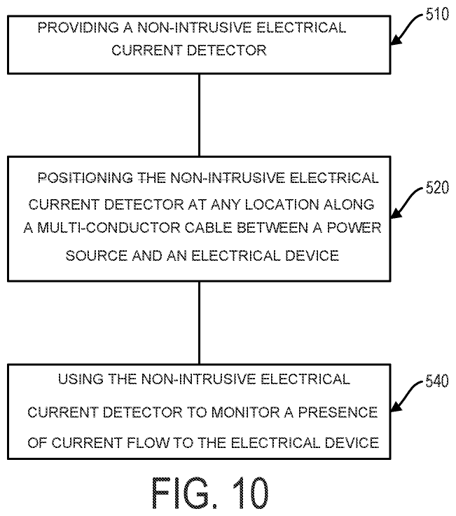

FIG. 10 illustrates one example of a method of using a non-intrusive current sensor as described and illustrated herein. At 510, a non-intrusive electrical current detector is provided. The non-intrusive electrical current detector may be made of a multiple axis magnetic sensor or multiple, single axis magnetic sensors. At 520, the non-intrusive electrical current detector is positioned along a multi-conductor cable between a power source and an electrical device. In one example, the non-intrusive current sensor is at least partially positioned about a cable having multiple conductors that is electrically connected to the electrical device. At 540, the non-intrusive electrical current detector is used to monitor a presence of current flow to the electrical device.

The invention provides a unique and simple way for a person to install the non-intrusive electrical current detector. The non-intrusive electrical current sensor is installed on a cable that supplies power to the device to be monitored, so the electrical current used by the device to be monitored passes through the non-intrusive electrical current sensor. It is no longer necessary to separate the conductors contained in the cable in order to measure the presence of current in the cable conductors. Installers of the non-intrusive electrical current detector, disclosed, simply attach the device to the cable that is used to power the device to be monitored. There is no need to make any kind of mechanical type electrical connection or separate the individual conductors of the power cable.

It is to be understood that the features of the various exemplary embodiments described herein may be combined with each other, unless specifically noted otherwise.

Although specific examples have been illustrated and described herein, a variety of alternate and/or equivalent implementations may be substituted for the specific examples shown and described without departing from the scope of the present disclosure. This application is intended to cover any adaptations or variations of the specific examples discussed herein. Therefore, it is intended that this disclosure be limited only by the claims and the equivalents thereof

1. A non-intrusive electrical current detector comprising:
a housing positionable about a multi-conductor cable; and
a multiple magnetic field sensing device located in the housing that senses a magnetic field any time an electrical current is present in the multi-conductor cable.

2. The detector of claim 1 comprising:
wherein the housing includes a notch suitable for containing the multi-conductor cable.

3. The detector of claim 2 comprising:
a mechanism for holding the multi-conductor cable within the notch.

4. The detector of claim 1, comprising where the multiple magnetic field sensing device is a multiple axis magnetic field sensing device.

5. The detector of claim 4, where the multiple axis magnetic field sensor comprises more than one single axis magnetic field sensors.

6. The detector of claim 4, where the multiple axis magnetic field sensor includes a single sensor that is a multiple axis magnetic field sensor.

7. The detector of claim 6, where the multiple axis magnetic field sensor is a 3 axis magnetic field sensor.

8. The detector of claim 4, comprising a printed circuit board positioned in the housing adjacent the notch, where the multiple magnetic field sensing device is positioned on the printed circuit board.

9. The detector of claim 1, where the magnetic sensor is a hall effect magnetic sensor.

10. A non-intrusive electrical current detection system comprising:
a multiple magnetic field sensing device positionable about a multi-conductor cable that senses a magnetic field any time an electrical current is present in the multi-conductor cable, and provides an output signal representative of the sensed electrical curent; and
a controller in communication with the multiple magnetic field sensing device that receives the output signal.

11. The system of claim 10, comprising:
a housing, where the multiple magnetic field sensing device and the controller are located in the housing.

12. The system of claim 10, comprising a visual display that provides a visual indication representative of an amount of time current is present in the cable.

13. The system of claim 10, comprising:
a wireless communication link associated with the controller for communication with a control system remote from the non-intrusive current detection system.

14. The system of claim 13, where the wireless communication link is a Bluetooth communication link.

15. The detector of claim 10, comprising where the multiple magnetic field sensing device is a multiple axis magnetic field sensing device.

16. The detector of claim 15, where the multiple axis magnetic field sensing device comprises more than one single axis magnetic field sensors.

17. The detector of claim 15, where the multiple axis magnetic field sensing device includes a single sensor that is a multiple axis magnetic field sensor.

18. The detector of claim 17, where the multiple axis magnetic field sensor is a 2 or 3 axis magnetic field sensor.

19. A pump monitoring system comprising:
a multi-conductor cable extending between a power source and an electric device;
a multiple magnetic field sensing device positionable about the multi-conductor cable that senses a magnetic field any time an electrical current is present in the multi-conductor cable, and provides an output signal representative of the sensed electrical current; and
a controller in communication with the multiple magnetic field sensing device that receives the output signal.

20. The system of claim 19, where the multiple axis magnetic field sensing device comprises more than one single axis magnetic field sensors.

21. The system of claim 19, where the multiple axis magnetic field sensing device includes a single sensor that is a multiple axis magnetic field sensor.

22. The system of claim 19, where the electric device is a pump.

23. The system of claim 19, the controller comprising a wireless communication link for transmitting a signal to a location remote from the electrical device that is representative of the run time of the electrical device

24. A method of monitoring an electrical device comprising:
providing a non-intrusive electrical current detector, the non-intrusive electrical current detector comprising a multiple axis magnetic field sensing device;
positioning the non-intrusive electrical current detector at any location along a multiconductor cable between a power source and an electrical device; and
using the non-intrusive electrical current detector to monitor a presence of current flow to the electrical device.
